(19) United States
(12) Patent Application Publication
(10) Pub. No.: US 2002/0132472 A1
(43) Pub. Date: Sep. 19, 2002

(54) Method for forming metal plug

(75) Inventor: Chang Soo Park, Seoul (KR)

Correspondence Address: MARGER JOHNSON & MCCOLLOM PC, 1030 SW MORRISON STREET, PORTLAND, OR, 97205, US

(73) Assignee: Jusung Engineering Co., Ltd., Kawagju-gun (KR)

(21) Appl. No.: 10/098,947

(22) Filed: Mar. 14, 2002

(30) Foreign Application Priority Data
Mar. 14, 2001 (KR) 2001-13127

(51) Int. Cl. H01L 21/44

(52) U.S. Cl. 438/641; 438/597; 438/607; 438/637

(57) ABSTRACT

Disclosed is a method of forming a metal plug which selectively forms the metal plug within a contact hole or a via hole in a simple manner. The method of the invention comprises the following steps of: (a) forming an insulation film having a contact hole on a lower structure, the contact hole exposing the lower structure; (b) forming a diffusion barrier with a uniform thickness on the whole surface of the resultant structure of the (a) step; (c) exposing the resultant structure having the diffusion barrier to an oxygen plasma atmosphere or an ozone plasma atmosphere to form a nucleation-preventing film made of an oxide on the surface of the diffusion barrier outside the contact hole; and (d) depositing a metal only inside the contact hole via a CVD to form the metal plug. According to the present invention, the manufacturing yield is improved whereas the manufacturing cost thereof is saved.

### BACKGROUND OF THE INVENTION

1. Field of the Invention

The present invention relates to methods of forming metal plugs, and more particularly, to a method of selectively forming a metal plug within a contact hole or a via hole.

2. Description of the Related Art

As well known to those skilled in the art, a sputtering which has been generally adopted as a method of forming metal lines can hardly fill contact holes without voids due to a so-called shadowing effect. In particular, such a problem becomes more remarkable as the aspect ratios of the contact holes are increasing.

In order to solve the above drawback, a number of studies have been made about methods for filling the contact holes with tungsten (W) via a selective tungsten CVD process or a blanket tungsten CVD process for performing chemical vapor deposition of tungsten. However, tungsten filled into the contact holes increases contact resistance by a large amount since the electrical resistivity of tungsten is two times higher than that of aluminum.

In particular, the selective tungsten CVD process is rarely applied due to low selectivity whereas the blanket tungsten CVD process leaves tungsten residues which are not sufficiently removed in a blanket-etching thereby degrading electrical properties of the semiconductor devices.

Therefore, currently proposed is a method which selectively forms aluminum within the contact holes to fill the same.

FIG. 1A to FIG. 1D are sectional views illustrating a method of forming a contact plug of the prior art.

FIG. 1A is a sectional view illustrating a step of forming a contact hole A and a diffusion barrier 14. First, an insulation film 12 made of boro-phospho-silicate-glass (BPSG) is formed on a silicon substrate 10, and then the insulation film 12 is anisotropically etched to form a contact hole A exposing the silicon substrate 10. Thereafter, a diffusion barrier 14 having a uniform thickness is formed on the whole surface of the substrate 10 having the contact hole A.

FIG. 1B is a sectional view illustrating a step of forming a silicon film 16. To be specific, the substrate having the diffusion barrier 14 is exposed in SiH₄ plasma atmosphere for several tens of seconds. At this time, SiH₄ plasma only contacts with the surface outside the contact hole A without reaching the inside of the contact hole A. Therefore, the silicon film 16 is formed only on the diffusion barrier 14 outside the contact hole A.

Alternatively, aluminum may be deposited via a sputtering rather than forming the silicon film 16 using SiH₄ plasma. Since the sputtering has a straightforward deposition characteristic, aluminum may be deposited only outside the contact hole A as above by using a shadow effect.

FIG. 1C is a sectional view illustrating a step of forming an aluminum (Al) plug 18. First, a resultant substrate having the silicon film 16 is exposed in an oxygen atmosphere. Since it is thermodynamically stable that silicon exists in the form of a silicon oxide, a natural oxide film (not shown) is formed only on the surface of the silicon film 16 and the upper portion of a side wall of the contact hole. As described in FIG. 1B, the same result is obtained from the Al film which is formed in place of the silicon film 16.

Then, after the resultant substrate having the natural oxide film is loaded into an Al CVD chamber, Dimethyl Aluminum Hydride (hereinafter will be referred to as “DMAH”) is flown into the chamber together with hydrogen gas. In this case, Al grows more rapidly inside the contact hole A where the natural oxide film is not formed than outside the contact hole A where the natural oxide film is formed because the natural oxide film prevents nucleation of Al. Therefore, the Al plug 18 is selectively formed only within the contact hole A.

FIG. 1D is a sectional view illustrating a step of forming a conductive film 20. The conductive film 20 is formed on the whole surface of the substrate with a uniform thickness. Therefore, the conductive film 20 is electrically connected to the substrate 10 via the Al plug 18.

According to the method of forming the contact plug of the prior art, although the Al plug 18 can be selectively formed only within the contact hole A, the steps of forming the silicon film 18 and oxidation should be accompanied in order to prevent the nucleation for the Al plug 18. Therefore, the foregoing method is sophisticated and has many process steps thereby lowering productivity per unit time.

Further, if the process has a long idle time for forming the Al plug 18 after the step of forming the natural oxide film, moisture existing in the air of a clean room is absorbed into the natural film. This requires an additional thermal process for removing the absorbed moisture.

In the meantime, after oxidation, the silicon film 18 or the Al film as a substitute thereof is hardly etched by a chlorine-containing gas which is mainly used in a dry etching. This causes a large amount of ion energy or a long etching time to a step of finishing metal lines, i.e. the step of dry etching the conductive film 20 and the diffusion barrier 14 for exposing the insulation film 12, after the step of FIG. 1D. Accordingly the above process is not adequate considering the yield thereof. Further, a photoresist pattern functioning as an etch barrier should be formed thick thereby elevating the manufacturing cost.

### SUMMARY OF THE INVENTION

Accordingly the present invention has been proposed to solve the foregoing problems of the prior art and it is an object of the invention to provide a method of forming a metal plug which selectively forms the metal plug within a contact hole or a via hole in a simple manner so as to overcome the foregoing problems of the prior art.

In accordance with an aspect of the invention to obtain the foregoing technical object, a method of forming a metal plug comprises the following steps of: (a) forming an insulation film having a contact hole on a lower structure, the contact hole exposing the lower structure; (b) forming a diffusion barrier with a uniform thickness on the whole surface of the resultant structure of the (a) step; (c) exposing the resultant structure having the diffusion barrier to an oxygen plasma atmosphere or an ozone plasma atmosphere to form a nucleation-preventing film made of an oxide on the surface of the diffusion barrier outside the contact hole; and (d) depositing a metal only inside the contact hole via a CVD to form the metal plug.

In the method of the invention, it is preferred that the diffusion barrier is made of TiN and the nucleation-preventing film is made of TiOₓ. Preferably, the (d) step of forming the metal plug is carried out after the step (c) of forming the nucleation-preventing film without exposing the resultant structure having the nucleation-preventing film to the open air. Further, the (c) step of forming the nucleation-preventing film is carried out at a temperature ranging from 200 to 500° C.

In the meantime, it is preferred that the metal deposited via the CVD is Al and the CVD uses gases containing DMAH and hydrogen, respectively, the CVD is carried out at a temperature ranging from 250 to 400° C. and under a pressure lower than the atmospheric pressure.

### BRIEF DESCRIPTION OF THE DRAWINGS

FIG. 1A to FIG. 1D are sectional views illustrating a method of forming a contact plug of the prior art; and

FIG. 2A to FIG. 2D are sectional views illustrating a method of forming a contact plug in accordance with an embodiment of the invention.

### DETAILED DESCRIPTION OF THE PREFERRED EMBODIMENT

The following detailed description will present a preferred embodiment of the present invention in reference to the accompanying drawings.

Although the preferred embodiment of the invention will illustrate a method which forms an Al contact plug on a silicon substrate, other kinds of metal such as copper (Cu), tungsten (W) and molybdenum (Mo) may be used as a material of a metal plug instead of Al. Of course, the technique of this embodiment can be applied to via holes in use for interconnection between multi-layered metals in addition to the contact plug for connecting between the silicon substrate and metal.

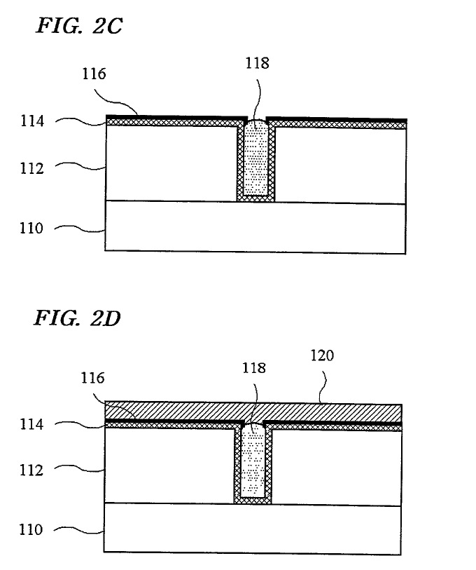

FIG. 2A to FIG. 2D are sectional views illustrating a method of forming a contact plug in accordance with an embodiment of the invention.

FIG. 2A is a sectional view illustrating a step of forming a contact hole A′ and a diffusion barrier 114. First, after an insulation film 112 made of BPSG is formed on a silicon substrate 100, the insulation film 112 is anisotropically etched to form the contact hole A′ exposing the silicon substrate 100. Then, a resultant substrate having the contact hole A′ is cleaned with H₂SO₄ and diluted HF to remove organic material and natural oxides existing on the silicon substrate 100 at the bottom of the contact hole A′.

Then, on the whole surface of the substrate 100 having the contact hole A′ is formed a diffusion barrier 114, e.g. a TiN film, with a uniform thickness to prevent any reaction between the silicon substrate 100 and an Al plug (designated with the reference numeral 118 in FIG. 2C). Prior to formation of the diffusion barrier 114, an ohmic contact layer, e.g. a Ti layer, may be further formed for ohmic contacts.

FIG. 2B is a sectional view illustrating or a step of forming a nucleation-preventing film 116, i.e. a film for preventing nucleation, in accordance with a characteristic of the invention. To be specific, the substrate having the diffusion barrier 114 is exposed to an oxygen plasma or ozone plasma atmosphere so as to form the nucleation-preventing film 116 such as a TiOₓ film with a thickness of 5 nm or less only on the surface of the diffusion barrier 114 outside the contact hole A′. The step of forming the nucleation-preventing film 116 is carried out for about 30 seconds at a substrate temperature of 250° C., a chamber pressure of 7 mTorr and an electric power of about 100W applied to plasma.

The mean free path of oxygen components in plasma may be so adjusted to prevent the oxygen components from entering the contact hole A′ thereby oxidizing only the outside of the contact hole A′ as above. In general, the lighter a gas is, the more dispersed it is at the entrance of the contact hole thereby rarely penetrating into the contact hole so that plasma formed by the lighter gas generates a plasma effect only outside the contact hole.

FIG. 2C is a sectional view illustrating a step of forming the Al plug 118. To be specific, a resultant substrate having the nucleation-preventing film 116 is loaded into an Al CVD chamber without exposition to the open air, and an Al source gas, e.g. DMAH optionally containing 5% Trimethyl Al (TMA) is flown into the chamber together with hydrogen gas functioning as a carrier gas at a temperature of about 350° C. for a time period of several minutes or less. If Ar or He gas is used as the carrier gas, hydrogen is separately added as a reducing agent.

Al grows more rapidly within the contact hole A′ than outside the contact hole A′ because the nucleation-preventing film 116 is not formed within the contact hole A′. Therefore, the Al plug 118 is selectively formed within the contact hole A′.

FIG. 2D is a sectional view illustrating a step of forming a conductive film 120. To be specific, a resultant substrate having the Al plug 118 is moved into a sputter chamber without exposition to the open air so as to form the flat conductive film 120. In order to obtain the conductive film 120 composed of Al, Al is deposited at a temperature ranging from 450 to 500° C. or Al is deposited at a lower temperature before performing a heat treatment at a higher temperature of 500° C. or above so as to cause reflow of Al.

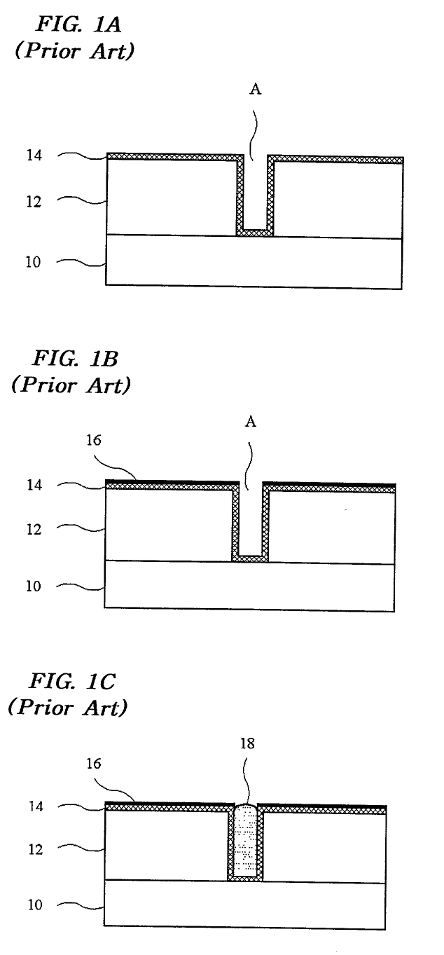

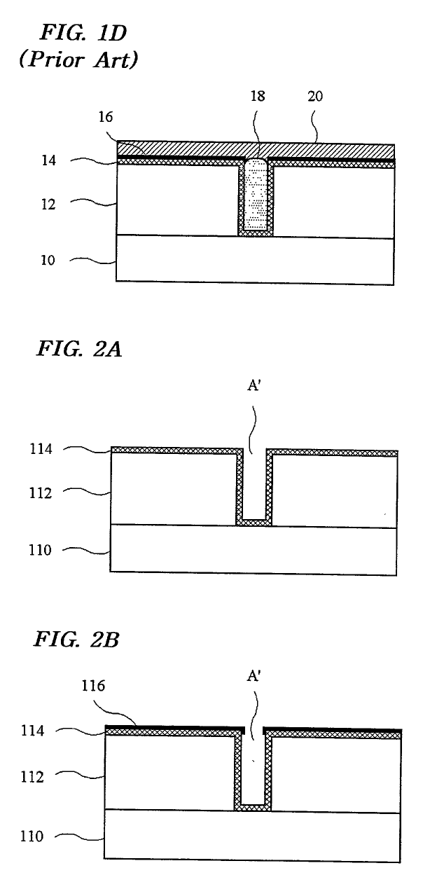

As described hereinbefore, the method of forming a contact plug in accordance with the preferred embodiment of the invention forms the nucleation-preventing film 116 for Al by oxidizing the diffusion barrier 114 without farther forming the silicon film 16 (FIG. 1B) differently from the conventional method and thus has a simpler process. Further, the Al plug 118 is formed without exposition to the open air after forming the nucleation-preventing film 116 thereby excluding the additional step of removing moisture as in the conventional method.

Further, even the oxidized TiN film is readily cleared by the Cl-containing gas, which is mainly used in the dry etching, thereby causing high ion energy or a long etching time unnecessary in performing the dry etching to the conductive film 120 and the diffusion barrier 116. Moreover, the photoresist pattern functioning as an etch barrier is not necessarily formed thick. Therefore, the manufacturing yield is improved whereas the manufacturing cost thereof is saved.

Although the preferred embodiments of the present invention have been disclosed for illustrative purposes, those skilled in the art will appreciate that various modifications, additions and substitutions can be made without departing from the scope and spirit of the invention as disclosed in the accompanying claims.

What is claimed is:

1. A method of forming a metal plug, the method comprising the following steps of:
(a) forming an insulation film having a contact hole on a lower structure, the contact hole exposing the lower structure;
(b) forming a diffusion barrier with a uniform thickness on the whole surface of the resultant structure of the (a) step;
(c) exposing the resultant structure having the diffusion barrier to an oxygen plasma atmosphere or an ozone plasma atmosphere to form a nucleation-preventing film made of an oxide on the surface of the diffusion barrier outside the contact hole; and
(d) depositing a metal only inside the contact hole via a CVD to form the metal plug.

2. The method of forming a metal plug in accordance with claim 1, wherein the diffusion barrier is made of TiN, and the nucleation-preventing film is made of a TiOₓ.

3. The method of forming a metal plug in accordance with claim 1, wherein said (d) step of forming the metal plug is carried out after said step (c) of forming the nucleation-preventing film without exposing the resultant structure having the nucleation-preventing film to the open air.

4. The method of forming a metal plug in accordance with claim 1, wherein said (c) step of forming the nucleation-preventing film is carried out at a temperature ranging from 200 to 500° C.

5. The method of forming a metal plug in accordance with claim 1, wherein the metal deposited via the CVD is aluminum, and wherein the CVD uses gases containing DMAH and hydrogen, respectively.

6. The method of forming a metal plug in accordance with claim 5, wherein the CVD is carried out at a temperature ranging from 250 to 400° C.

7. The method of forming a metal plug in accordance with claim 1, wherein the CVD is carried out under a pressure lower than the atmospheric pressure.
